(19) United States
(12) Patent Application Publication
(10) Pub. No.: US 2002/0142610 A1
(43) Pub. Date: Oct. 3, 2002

(54) Plasma etching of dielectric layer with selectivity to stop layer

(76) Inventors: Ting Chien, Cupertino, CA (US); Christine Nelson, Santa Clara, CA (US); Douglas Keil, Fremont, CA (US)

Correspondence Address: Peter K. Skiff, BURNS, DOANE, SWECKER & MATHIS, L.L.P., P.O. Box 1404, Alexandria, VA, 22313-1404, US

(21) Appl. No.: 09/820,692

(22) Filed: Mar. 30, 2001

(51) Int. Cl. H01L 21/302; H01L 21/461

(52) U.S. Cl. 438/710

(57) ABSTRACT

A semiconductor manufacturing process wherein a dielectric layer is plasma etched with selectivity to an underlying and/or overlying stop layer such as a silicon nitride layer. The etchant gas includes a hydrogen-free fluorocarbon reactant such as CₓF_{y} gas wherein y/x ≦1.5, an oxygen-containing gas such as O₂ and a carrier gas such as Ar. The etch rate of the dielectric layer can be at least 10 times higher than that of the stop layer. Using a combination of C₄F₆, O₂ and Ar, it is possible to obtain dielectric: nitride etch selectivity of greater than 30:1 and nitride cornering etch selectivity of greater than 20:1. The process is useful for etching vias, contacts, and/or trenches of a self-aligned contact (SAC) or self-aligned trench.

### FIELD OF THE INVENTION

The present invention relates to an improved method for plasma etching a dielectric layer in the fabrication of integrated circuits.

### DESCRIPTION OF THE RELATED ART

A common requirement in integrated circuit fabrication is plasma etching of openings such as contacts, trenches and vias in dielectric materials. The dielectric materials include doped silicon oxide such as fluorinated silicon oxide (FSG), undoped silicon oxide such as silicon dioxide, silicate glasses such as boron phosphate silicate glass (BPSG) and phosphate silicate glass (PSG), doped or undoped thermally grown silicon oxide, doped or undoped TEOS deposited silicon oxide, organic and inorganic low-k materials, etc. The dielectric dopants include boron, phosphorus and/or arsenic. The dielectric can overlie a conductive or semiconductive layer such as polycrystalline silicon, metals such as aluminum, copper, titanium, tungsten, molybdenum or alloys thereof, nitrides such as titanium nitride, metal suicides such as titanium silicide, cobalt silicide, tungsten silicide, molybdenum silicide, etc.

Various methods have been used to obtain desired selectivity ratios during etching. For example, U.S. Pat. No. 5,786,276 discloses a chemical downstream etching technique intended to be selective to silicon nitride over silicon oxide using a CH₃F/CF₄/O₂ recipe and a CH₂F₂/CF₄/O₂ recipe. U.S. Pat. No. 6,174,451 discloses the use of higher-order fluorocarbons with a finite hydrogen content to achieve an oxide etch with a high nitride selectivity, including using more heavily polymerizing gases to obtain nitride faceting selectivity. Other patents relating to plasma etch processes with selectivity to silicon nitride include U.S. Pat. Nos. 5,503,901; 5,595,627;5,843,847; 5,928,967; 6,066,566; 6,074,959; 6,159,862; 6,174,451; and 6,183,655.

The deleterious effect on critical dimensions encountered in self aligned contact (SAC) structures is applicable in a dual damascene structure. In a dual damascene structure, exposure of surfaces, including corners, to multiple etch processes may impact CD and verticality of features. Therefore, there is a need in dual damascene structures for etch recipes that may be utilized to etch oxides and that have a high selectivity to nitride.

U.S. Pat. No. 6,153,514 discloses a method of forming a self-aligned dual damascene structure which includes conductive, dielectric, and etch stop layers and masks. The etch stop layer may be silicon nitride, the dielectric layer may be a low-k dielectric material wherein k<4, and the hard mask layer may be silicon nitride. According to this patent, the etch stop layer is etched with CHF₃/N₂, the dielectric layer is etched with N₂/H₂O₂, C₄F₈/Ar/O₂/CO, or N₂/H₂, and the nitride hard mask layer is etched with CHF₃/N₂.

U.S. Patent No. 6,156,642 discloses a dual damascene structure wherein a semiconductor substrate includes a bottom metallization layer (e.g., copper), a topping layer (e.g., silicon nitride), a dielectric layer (e.g., silicon oxide or other low-k material), a conformal layer (e.g., titanium, titanium nitride, tantalum, tantalum nitride, tungsten nitride) covering sidewalls of a trench and via hole, and a passivation layer (e.g., silicon nitride or silicon carbide).

U.S. Pat. No. 6,143,641 discloses a dual damascene structure in an integrated circuit structure which includes an intermetal dielectric material (e.g., SiO₂) on an underlying conductive material (e.g., aluminum or copper), an adhesion layer (e.g., Ti, TiN, Ta) on exposed sidewalls of the dual damascene via structure which is filled with copper, a barrier metal or layer of silicon nitride, and additional layers including a low-k dielectric material, silicon dioxide and silicon nitride.

As device geometries become smaller and smaller, the need for high etch selectivity is even greater in order to achieve plasma etching of deep and narrow openings in dielectric layers. Accordingly, there is a need in the art for a plasma etching technique which provides high etch selectivity and/or which achieves deep and narrow openings. Further, it would be highly desirable to achieve such opening geometries without bowing of the sidewalls of the openings (e.g., maintaining desired verticality).

### SUMMARY OF THE INVENTION

The invention provides a process for plasma etching a dielectric layer with selectivity to an underlying stop layer, comprising the steps of supporting a semiconductor substrate having a dielectric layer over a stop layer in a plasma etch reactor, supplying an etchant gas to the plasma etch reactor and etching openings in the dielectric layer by energizing the etchant gas into a plasma state. The etchant gas includes a hydrogen-free fluorocarbon gas represented by CₓF_{y} wherein y/x<1.5, an oxygen-containing gas and an optional inert carrier gas.

In a preferred embodiment, the stop layer can be silicon nitride and the etching process can be applied to etching applications requiring high dielectric:nitride etch selectivity, especially high dielectric:nitride cornering etch selectivity, such as in self-aligned contact (SAC) structures, self-aligned trench structures and dual-damascene structures.

According to one aspect of the invention, the dielectric layer comprises a doped or undoped silicon dioxide, BPSG, PSG, TEOS, thermal silicon oxide or low-k material such as SiLK. The openings can comprise grooves corresponding to a conductor pattern, via openings or contact openings. The openings can be etched in the dielectric layer so as to have a high aspect ratio, preferably an aspect ratio of at least 3:1. The fluorocarbon reactant can be one or more gases selected from the group of C₂F₂, C₂F₃, C₃F₄, C₄F₄, C₄F₆, C₅F₆, C₆F₆, and C₆F₈. The semiconductor substrate can include an electrically conductive or semiconductive layer such as a metal-containing layer selected from the group consisting of Al, Al alloys, Cu, Cu alloys, Ti, Ti alloys, doped or undoped polycrystalline or single crystal silicon, TiN, TiW, Mo, silicides of Ti, W, Co and/or Mo or alloys thereof, etc. The optional carrier gas can be selected from the group consisting of Ar, He, Ne, Kr, Xe or mixtures thereof. The stop layer can comprise a silicon nitride layer provided over the dielectric layer and/or between the dielectric and conductive/semiconductive layers.

In a preferred embodiment, the stop layer is silicon nitride and the dielectric to silicon nitride etch rate selectivity is at least 10. In the case where the dielectric layer is BPSG and the openings open onto flat and corner portions of a silicon nitride stop layer, the etch rate selectivity of the BPSG to the flat and corner portions of the silicon nitride is at least 15.

The plasma etch reactor can comprise an ECR plasma reactor, an inductively coupled plasma reactor, a capacitively coupled plasma reactor, a helicon plasma reactor or a magnetron plasma reactor. For example, the plasma etch reactor can comprise a dual frequency capacitively coupled plasma reactor including an upper showerhead electrode and a bottom electrode, RF energy being supplied at two different frequencies to either the bottom electrode or at different first and second frequencies to the showerhead electrode and bottom electrode. However, the plasma etch reactor can comprise other types of reactors such as a capacitively coupled plasma reactor having a powered showerhead electrode and/or a powered bottom electrode, the showerhead electrode being supplied 0 to 3000 watts of RF energy and the bottom electrode being supplied 0 to 3000 watts of RF energy. Pressure in the plasma etch reactor can be set at 10 to 200 mTorr and/or temperature of the substrate support can be set at −20° C. to +80° C., more preferably the pressure can be set at 50 to 100 mTorr and/or the temperature of the substrate support can be set at +20° C. to +60° C.

In a preferred embodiment, the etchant gas is nitrogen-free, the Cₓ,F_{y} gas is at least C₄F₆, the oxygen containing gas is at least O₂ and the carrier gas is Ar, the etchant gas being supplied to the plasma etch reactor through a showerhead electrode at flow rates of 2 to 50 sccm C₄F₆, 2 to 50 sccm O₂ and 50 to 800 sccm Ar. For example, the etchant gas can be supplied to the plasma etch reactor through the showerhead electrode at flow rates of 10 to 25 sccm C₄F₆, 5 to 20 sccm O₂ and 50 to 300 sccm Ar. Preferably, a ratio of flow rates of the CₓF_{y} to oxygen containing reactant is 0.5:1 to 5:1, more preferably 1:1 to 2:1. If desired, the etchant gas can include CO supplied to the plasma etch reactor at a rate of 50 to 500 sccm CO. In a particular etch process, the Cₓ,F_{y} is either C₄F₆ or C₆F₆. For instance, the CₓF_{y} can be C₄F₆ and the oxygen containing gas can be O₂, the C₄F₆ and O₂ being supplied to the plasma etch reactor at flow rates having a ratio of C₄F₆:O₂ of 0.5:1 to 5:1, more preferably 1:1 to 2:1. The oxygen containing gas can be controlled so as to be supplied to the plasma etch reactor in an amount sufficient to avoid etch stop during etching of the openings.

### BRIEF DESCRIPTION OF THE DRAWINGS

FIGS. 1A-C show schematic representations of a single SAC structure which can be etched according to the process of the invention, FIG. 1A showing a pre-etch condition, FIG. 1B showing a post-etch condition in which an opening has been etched, FIG. 1C showing a post-etch condition in which the nitride at the bottom of the opening has been removed;

FIGS. 2A-C show schematic representations of a double SAC structure which can be etched according to the process of the invention, FIG. 2A showing a pre-etch condition, FIG. 2B showing a post-etch condition in which an opening has been etched, FIG. 2C showing a post-etch condition in which the nitride at the bottom of the opening has been removed;

FIGS. 3A-D show schematic representations of a via-first dual-damascene structure which can be etched according to the process of the invention, FIG. 3A showing a pre-etch condition, FIG. 3B showing a post-etch condition in which a via has been etched, FIG. 3C showing the structure re-patterned for a trench etch and FIG. 3D showing a post-etch condition in which the trench has been etched;

FIGS. 4A-D show schematic representations of a trench-first dual-damascene structure which can be etched according to the process of the invention, FIG. 4A showing a pre-etch condition, FIG. 4B showing a post-etch condition in which a trench has been etched, FIG. 4C showing the structure re-patterned for a via etch and FIG. 4D showing a post-etch condition in which the via has been etched;

FIGS. 5A-B show schematic representations of a self-aligned dual-damascene structure which can be etched according to the process of the invention, FIG. 5A showing a pre-etch condition and FIG. 5B showing a post-etch condition in which a trench and a via have been etched;

FIG. 6 shows a schematic representation of an inductively coupled high density plasma reactor which can be used to carry out the process of the invention; and

FIG. 7 shows a schematic representation of a medium density parallel plate plasma reactor which can be used to carry out the process of the invention.

### DETAILED DESCRIPTION OF THE INVENTION

The invention provides a semiconductor manufacturing process wherein openings can be plasma etched in dielectric layers while providing desired selectivity to underlying stop layers. The stop layers can comprise silicon nitride, silicon carbide, silicon oxynitride, silicon carbonitride, or other suitable stop layer. For example, the stop layer can comprise a silicon nitride corner of a single or double SAC structure. The dielectric layer can comprise doped and undoped silicon oxide such as TEOS and the like, silicate glass such as PSG and BPSG, an organic low-k dielectric material such as SiLK or an inorganic low-k material such as OSG.

In a preferred embodiment, the invention provides a process of plasma etching a dielectric layer with selectivity to a silicon nitride stop layer which may include a nitride corner feature. Such selectivity is of great interest in the manufacture of SAC structures wherein a silicon nitride conformal layer has an exposed corner or shelf and in the manufacture of damascene structures wherein one or more silicon nitride layers are incorporated in a multilayer structure. During manufacture of such structures, features such as contacts, vias, conductor lines, etc., are etched in dielectric materials such as oxide layers in the manufacture of integrated circuits. The invention overcomes a problem with prior etching techniques by increasing the etch rate selectivity between the dielectric layer and the underlying and/or overlying silicon nitride layers, including the selectivity of flat surfaces and corner features.

According to another aspect of the invention, a SAC or a single or dual-damascene etch process is provided wherein doped and undoped oxide films (BPSG, PSG, TEOS) can be etched with an oxide:stop layer etch selectivity of greater than 10:1, preferably greater than 20:1, and most preferably greater than 30:1. The process can provide a low or reversed RIE lag, which can allow multilevel dielectric etch applications and enable the fabrication of dual-damascene devices.

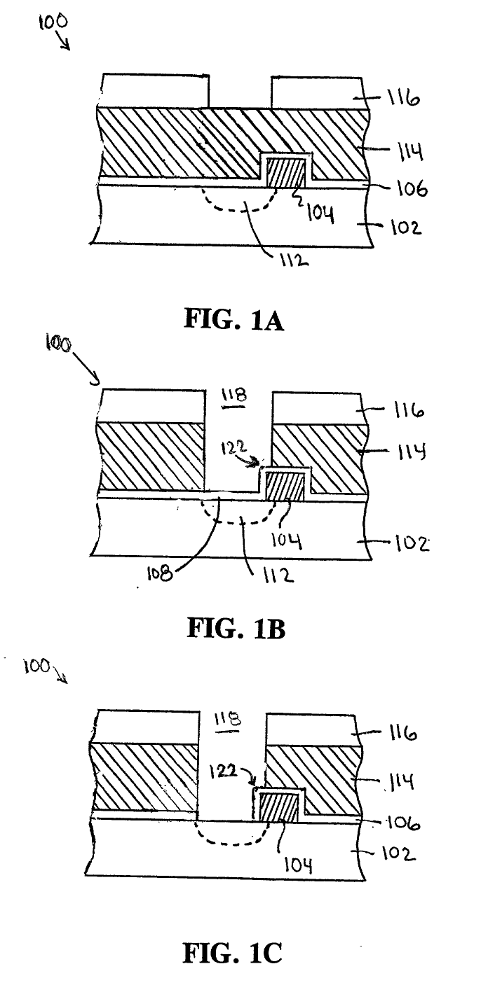

FIGS. 1A-C show a sequence of steps which can be used to manufacture a single self-aligned contact (SAC) structure 100 formed by a transistor on a silicon substrate 102. The transistor is photolithographically formed into a gate structure 104 and a substantially conformal layer 106 of silicon nitride (Si₃N₄) is deposited by, for example, chemical vapor deposition (CVD) and coats the top and sides of the gate structure 104 as well as the bottom 108 of hole 118. Although silicon nitride is commonly used as a stop layer for oxide etch applications, other materials such as silicon carbide, silicon oxynitride, silicon carbonitride and the like can be used as the stop layer. Dopant ions are ion implanted using the gate structure 104 as a mask to form a self-aligned p-type or n-type well 112, which acts as a common source for the transistor. The drain structure of the transistor is not illustrated.

A dielectric layer such as an oxide layer 114 is deposited over the gate structure and may be followed by a photoresist layer 116. The oxide layer may be BPSG or other oxide having any desired thickness such as 6000 to 7000 Å. As shown in FIG. 1A, the photoresist layer 116 is patterned to define the openings 118. The dielectric layer 114 can be etched in accordance with the invention to extend the openings 118 to the silicon nitride layer 106, as shown in FIG. 1B. During this etching step, the conformal layer 106 acts as an etch stop for the process. The contact hole 118 can have a size smaller than 0.30 μm, e.g., 0.25 μm. As shown in FIG. 1C, a subsequent etch may remove a portion of the conformal layer 106 at the bottom 108 of the hole 118. A conductor (not shown) is then backfilled into the contact hole 118 and contacts the silicon substrate 102 and the silicon nitride acts as an electrical insulator for the conductor.

Because the nitride acts as an insulator, the SAC structure 100 and process offer the advantage that the contact hole 118 may be wider than the width of the bottom CD at the gate structure 104. Additionally, the photolithographic registry of the contact hole 118 with the gate structure 104 need not be precise. However, to achieve these beneficial effects, the SAC oxide etch should produce an oxide etch rate that is greater than the nitride etch rate (e.g., must be highly selective to nitride). Numerical values of selectivity are calculated as the ratio of the oxide to nitride etch rates.

Selectivity is especially desired at the corner 122 of the conformal layer 106 above and next to the bottom of the hole 118 since corners 122 of nitride have a geometry favorable to fast etching that tends to create facets and the corners 122 are exposed the longest to the oxide etch. The etch process of the invention provides high selectivity to nitride to avoid problems such as electrical shorting in the final device which could otherwise occur due to loss of nitride at the corner 122.

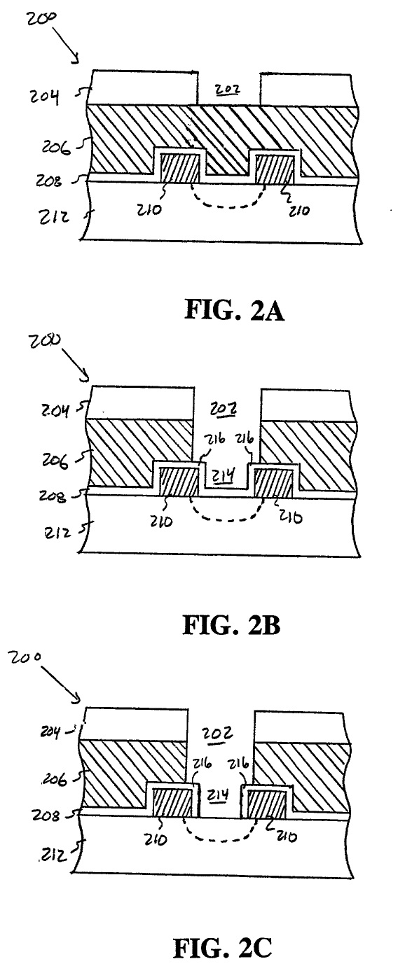

FIG. 2A-C show schematics of how a SAC structure 200 can be etched in accordance with the invention. FIG. 2A shows a pre-etch condition wherein an opening 202 is provided in a photoresist masking layer 204 which overlies a stack of a first dielectric layer 206 such as silicon oxide, a stop layer 208 such as silicon nitride, gate structures 210, and a substrate 212 such as a silicon wafer. The opening 202 corresponds to the gap 214 between the gate structures 210. FIG. 2B shows the structure after etching wherein the opening 202 extends through the dielectric layer 206 to the stop layer 208. By the present invention, the selectivity of oxide to nitride at the corners 216 (also called “corner selectivity”) is ≧20. FIG. 2C shows the structure after removal of the stop layer 208 at the bottom of the opening 202.

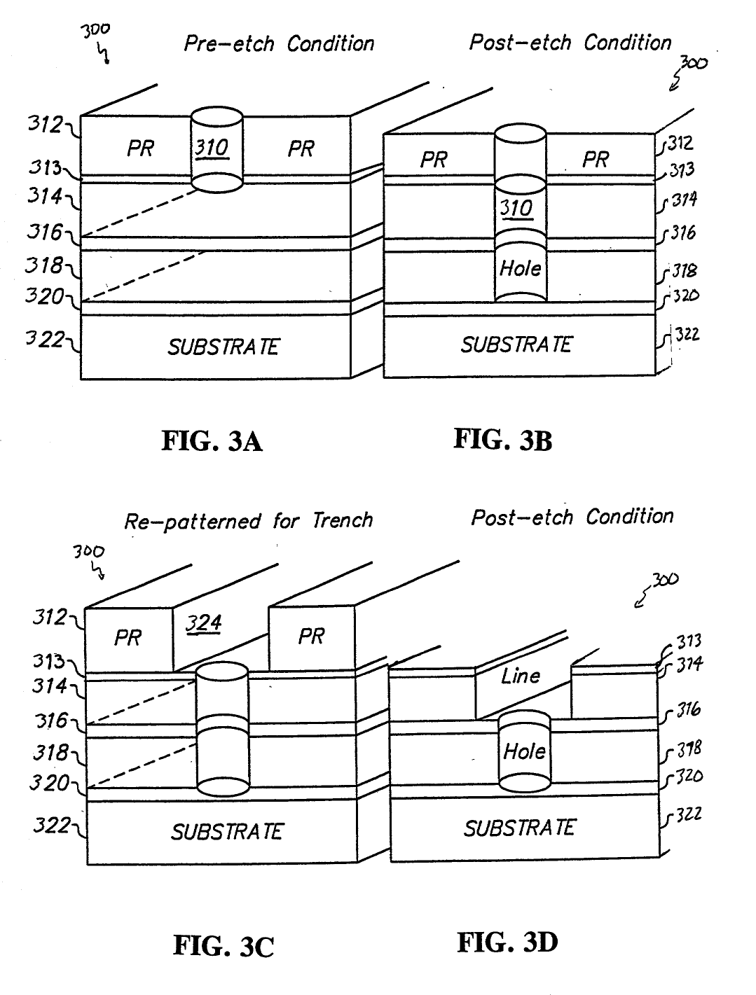

FIGS. 3A-D show schematics of how a via-first dual-damascene structure 300 can be etched in accordance with the invention. FIG. 3A shows a pre-etch condition wherein an opening 310 corresponding to a via is provided in a photoresist masking layer 312 which overlies a stack of a hard mask layer 313 such as silicon nitride, a first dielectric layer 314 such as silicon oxide, a first stop layer 316 such as silicon nitride, a second dielectric layer 318 such as silicon oxide, a second stop layer 320 such as silicon nitride, and a substrate 322 such as a silicon wafer. FIG. 3B shows the structure after etching wherein the opening 310 extends through the dielectric layers 314, 318 and first stop layer 316 to the second stop layer 320. FIG. 3C shows the structure after re-patterning the masking layer for a trench 324. FIG. 3D shows the structure after etching wherein the first dielectric layer 314 is etched down to the first stop layer 316 and the photoresist masking layer has been removed.

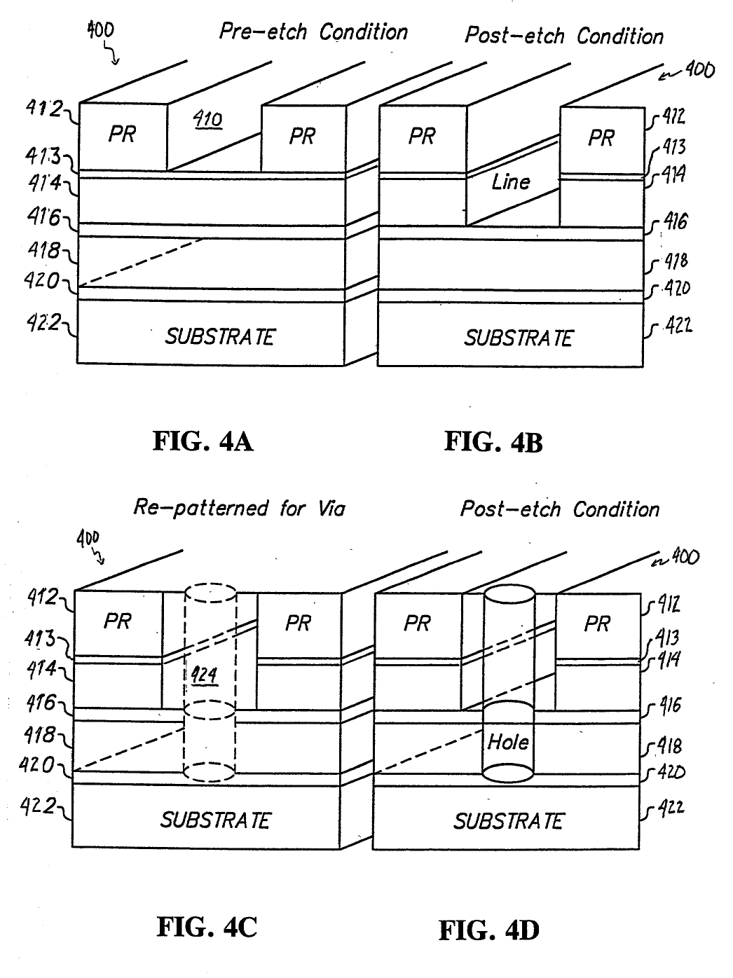

FIGS. 4A-D show schematics of how a trench-first dual-damascene structure 400 can be etched in accordance with the invention. FIG. 4A shows a pre-etch condition wherein an opening 410 corresponding to a trench is provided in a photoresist masking layer 412 which overlies a stack of a hard mask layer 413, a first dielectric layer 414 such as silicon oxide, a first stop layer 416 such as silicon nitride, a second dielectric layer 418 such as silicon oxide, a second stop layer 420 such as silicon nitride, and a substrate 422 such as a silicon wafer. FIG. 4B shows the structure after etching wherein the opening 410 extends through the dielectric layer 414 to the first stop layer 416. FIG. 4C shows the structure after re-patterning the masking layer for a via 424. FIG. 4D shows the structure after etching wherein the second dielectric layer 418 is etched down to the second stop layer 420 in the shape of a hole.

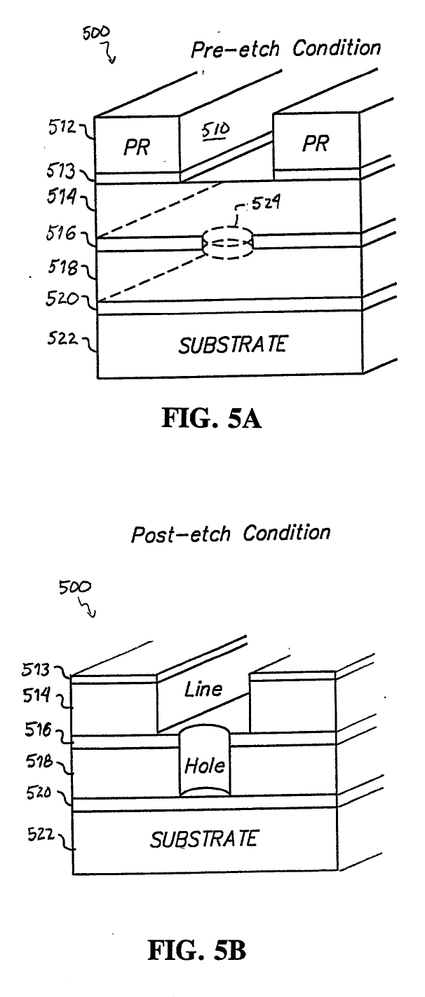

FIGS. 5A-B show schematics of how a dual-damascene structure 500 can be etched in a single step in accordance with the invention. FIG. 5A shows a pre-etch condition wherein an opening 510 corresponding to a trench is provided in a photoresist masking layer 512 which overlies a stack of a hard mask 513, a first dielectric layer 514 such as silicon oxide, a first stop layer 516 such as silicon nitride, a second dielectric layer 518 such as silicon oxide, a second stop layer 520 such as silicon nitride, and a substrate 522 such as a silicon wafer. In order to obtain etching of vias through the first stop layer 516 in a single etching step, first stop layer 516 includes an opening 524. FIG. 5B shows the structure after etching wherein the opening 510 extends through the dielectric layer 514 to the first stop layer 516 and the opening 524 extends through the second dielectric 518 to the second stop layer 520. Such an arrangement can be referred to as a “self-aligned dual-damascene” structure.

The process of the invention is applicable to etching of various low-k dielectric layers including doped silicon oxide such as fluorinated silicon oxide (FSG), silicate glasses such as boron phosphate silicate glass (BPSG) and phosphate silicate glass (PSG), organic polymer materials such as polyimide, organic siloxane polymer, poly-arylene ether, carbon-doped silicate glass, silsesquioxane glass, fluorinated and non-fluorinated silicate glass, diamond-like amorphous carbon, aromatic hydrocarbon polymer such as SiLK (a product available from Dow Chemical Co.), c-doped silica glass such as CORAL (a product available from Novellus Systems, Inc.), or other suitable dielectric material having a dielectric constant below 4.0, preferably below 3.0. The low-k dielectric can overlie an intermediate layer such as a barrier layer and a conductive or semiconductive layer such as polycrystalline silicon, metals such as aluminum, copper, titanium, tungsten, molybdenum or alloys thereof, nitrides such as titanium nitride, metal silicides such as titanium silicide, cobalt silicide, tungsten silicide, molydenum silicide, etc.

The plasma can be produced in various types of plasma reactors. Such plasma reactors typically have energy sources which use RF energy, microwave energy, magnetic fields, etc. to produce a medium to high density plasma. For instance, a high density plasma could be produced in a transformer coupled plasma (TCP™) available from Lam Research Corporation which is also called inductively coupled plasma reactor, an electron-cyclotron resonance (ECR) plasma reactor, a helicon plasma reactor, or the like. An example of a high flow plasma reactor which can provide a high density plasma is disclosed in commonly owned U.S. Pat. No. 5,820,261, the disclosure of which is hereby incorporated by reference. The plasma can also be produced in a parallel plate etch reactor such as the dual frequency plasma etch reactor described in commonly owned U.S. Pat. No. 6,090,304, the disclosure of which is hereby incorporated by reference.

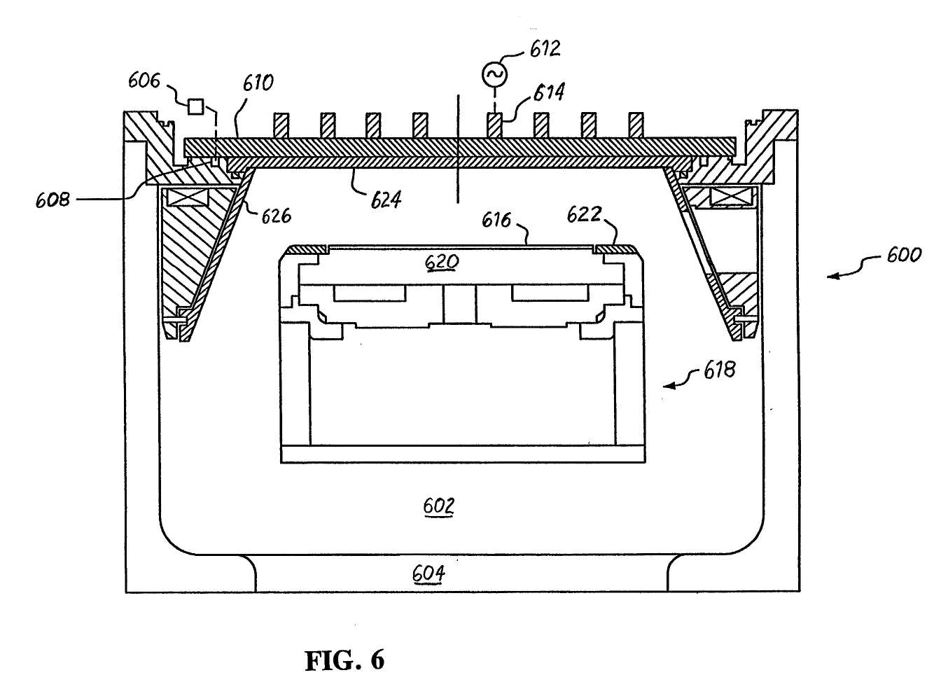

The process of the invention can be carried out in an inductively coupled plasma reactor such as reactor 600 shown in FIG. 6. The reactor 600 includes an interior 602 maintained at a desired vacuum pressure by a vacuum pump connected to an outlet 604 in a lower wall of the reactor. Etching gas can be supplied to a showerhead arrangement be supplying gas from gas supply 606 to a plenum 608 extending around the underside of a dielectric window 610. A high density plasma can be generated in the reactor by supplying RF energy from an RF source 612 to an external RF antenna 614 such as a planar spiral coil having one or more turns outside the dielectric window 610 on top of the reactor. The plasma generating source can be part of a modular mounting arrangement removably mounted in a vacuum tight manner on the upper end of the reactor.

A semiconductor substrate 616 such as a wafer is supported within the reactor on a substrate support 618 such as a cantilever chuck arrangement removably supported by a modular mounting arrangement from a sidewall of the reactor. The substrate support 618 is at one end of a support arm mounted in a cantilever fashion such that the entire substrate support/support arm assembly can be removed from the reactor by passing the assembly through an opening in the sidewall of the reactor. The substrate support 618 can include a chucking apparatus such as an electrostatic chuck 620 and the substrate can be surrounded by a dielectric focus ring 622. The chuck can include an RF biasing electrode for applying an RF bias to the substrate during an etching process. The etching gas supplied by gas supply 606 can flow through channels between the window 610 and an underlying gas distribution plate 624 and enter the interior 602 through gas outlets in the plate 624. The reactor can also include a conical or cylindrical heated liner 626 extending from the plate 624 .

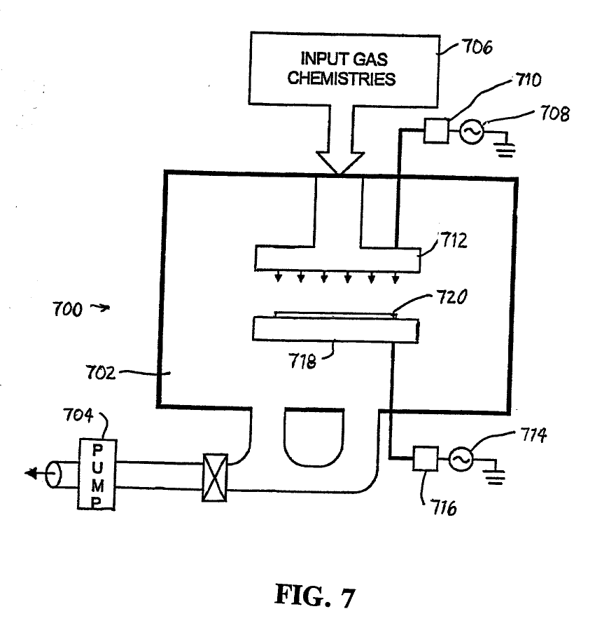

The process of the invention can also be carried out in a parallel plate plasma reactor such as reactor 700 shown in FIG. 7. The reactor 700 includes an interior 702 maintained at a desired vacuum pressure by a vacuum pump 704 connected to an outlet in a wall of the reactor. Etching gas can be supplied to a showerhead electrode 712 by supplying gas from gas supply 706. A medium density plasma (e.g., 10¹⁰ to 10¹¹ ions/cm³) can be generated in the reactor by supplying RF energy from RF sources 708,714 to the showerhead electrode 712 and a bottom electrode 718 or the showerhead electrode 712 can be electrically grounded and RF energy at two different frequencies can be supplied to the bottom electrode 718. Other types of plasma etch reactors can also be used such as reactors having only a single source of RF power supplied either to a top electrode or bottom electrode.

In one embodiment, the invention provides a process for plasma etching high aspect ratio features such as conductor lines, vias and contacts including self aligned contacts (SAC) in dielectric layers on semiconductor substrates. In the process, a gas mixture containing fluorocarbon, oxygen and optional gases such as a carrier gas (e.g., argon) is energized in a plasma etch reactor into a plasma state such that the fluorocarbon and the oxygen reactant are at least partially dissociated. During the etching process, the dielectric layer is etched by the fluorine and the carbon reacts with some free fluorine to thereby reduce the etch rate of the masking and/or stop etch layers. The oxygen is effective in providing a desired level of selectivity between the etch rates of the dielectric material being etched and an underlayer such as silicon nitride and/or an overlayer such as a photoresist while at the same time balancing polymer build-up sufficiently to protect sidewalls of etched features while avoiding pinch-off and etch stop problems due to excessive polymer build-up. Especially good selectivity of oxide to nitride can be obtained when the etch gas is free of hydrogen and/or nitrogen.

Etch stop is especially problematic during plasma etching of deep and narrow openings in dielectric materials such as silicon oxide using gas chemistries which form too much polymer, i.e., polymer-build-up in the opening prevents further etching of the silicon oxide. In the process of the invention, the polymer build-up can be reduced by the synergistic effect of breaking up the polymer with the oxygen in the etching gas mixture. Further, in order to preserve the critical dimension (CD) of the etched feature, the oxygen removes enough of the polymer build-up on the sidewalls and/or bottom walls of the etched openings to avoid excessive build-up of polymer on the sidewalls which otherwise could cause “etchstop” of the etched openings and thus prevent complete etching of the opening to the desired depth.

According to the invention, oxygen is added in an amount effective to control the etch rate selectivity of the etching gas chemistry. That is, the oxygen is effective to prevent etch stop by reacting with polymer at the bottom of the etched openings. The advantageous effects of the invention can be achieved by supplying the oxygen reactant and fluorocarbon reactant to plasma etching reactor at a flow rate ratio of oxygen reactant to fluorocarbon reactant of 1.5 or less. For selective etching of BPSG in a medium density plasma etch reactor, the flow rate ratio of oxygen reactant to fluorocarbon reactant is preferably 0.5 to 1.2.

The fluorocarbon is preferably hydrogen-free and may comprise at least one CₓF_{y} gas wherein y/x≦1.5, such gases including C₂F₂, C₂F₃, C₃F₄, C₄F₄, C₄F₆, C₅F₆, C₆F₆, C₆F₈, etc. The etching gas mixture may optionally include other gases and/or an inert carrier gas such as argon (Ar), helium (He), neon (Ne), krypton (Kr), xenon (Xe) and mixtures thereof. Argon is an especially useful inert carrier gas which aids fluorine in attacking dielectric materials such as silicon oxide. In order to maintain low pressure in the plasma etching reactor, the amount of carrier gas introduced into the reactor can be at low flow rates. For instance, for a medium to high density plasma reactor, argon can be supplied into the reactor in amounts of 100 to 300 sccm. The carrier gas preferably aids the dielectric etch rate, e.g., the oxide etching rate can be increased due to sputtering of the oxide.

The amount of fluorocarbon gas to be supplied to the plasma reactor should be sufficient to achieve the desired degree of polymerizing. Oxygen and fluorocarbon reactants can each be supplied at flow rates of 5 to 100 sccm, preferably 5 to 50 sccm, and more preferably 5 to 20 sccm. As an example, the oxygen reactant flow rate can range from 5 to 20 sccm when CₓF_{y} is supplied at 10 to 20 sccm, and argon, if supplied, can range from 100 to 300 sccm. In another example, the CₓF_{y} is C₄F₆, the oxygen containing gas is O₂ and the C₄F₆ and O₂ are supplied to the plasma etch reactor at flow rates having a ratio of C₄F₆:O₂ of 1:1 to 2:1. In an additional example, the C₄F₆ and O₂ are supplied to the plasma etch reactor at flow rates to avoid etch stop during etching of the openings in a SAC or dual damascene structure. The O₂ can be supplemented or replaced with other oxygen containing gases such as CO. For instance, CO can be added to the etch gas at a flow rate of 50 to 500 sccm. The amount of CO can be selected to provide a desired amount of oxygen and carbon in the etch gas to further enhance selectivity of the oxide:nitride etch rate selectivity.

It will be apparent to those skilled in the art that the flow rates of the various gases will depend on factors such as the size of the substrate, the type of plasma reactor, the power settings, the vacuum pressure in the reactor, the dissociation rate for the plasma source, etc.

The process of the invention is useful for obtaining extremely high dielectric:nitride etch selectivity of at least 10:1, the process being especially useful for obtaining aspect ratios up to 10:1 for openings smaller than 0.3 μm, preferably as small as 0.18 μm and below. For example, in one embodiment, a dual frequency plasma etch reactor (such as the dual frequency plasma etch reactor described in commonly owned U.S. Pat. No. 6,090,304, the disclosure of which is hereby incorporated by reference) was operated with a top electrode power of 200-3000 W, preferably 1000-2000 W, and a bottom electrode power of 50-3000 W, preferably 1000-2000 W, to achieve the desired etch selectivity. For example, etching of a BPSG layer can be carried out for about 1 minute in a single step with the chamber pressure set at about 80 mTorr, one or both of the electrodes powered with 1400 watts at 27 MHz and 1100 watts at 2 MHz, 260 sccm Ar, 12 sccm O₂, 11 sccm C₄F₆. In a two step process, an oxide etch can be carried out for about 1 minute with the chamber pressure set at about 80 mTorr, one or both of the electrodes powered with 1400 watts at 27 MHz and 1100 watts at 2 MHz, 260 sccm Ar, 13 sccm O₂ and 11 sccm C₄F₆ in the first step and for about 35 seconds with the same process conditions except for the O₂ flow rate being lowered to 11 sccm. With such oxide etch processes, it is possible to achieve oxide etch rates of 6000 to 7000 Å/minute, nitride etch rates of 200 to 300 Å/minute and oxide:nitride etch rate selectivities of over 20 in corner and/or flat areas of the silicon nitride which are exposed during etching of the openings.

The reactor pressure is preferably maintained at a level suitable for sustaining a plasma in the reactor. In general, too low a reactor pressure can lead to plasma extinguishment whereas in a high density etch reactor too high a reactor pressure can lead to the etch stop problem. For high density plasma reactors, the reactor is preferably at a pressure below 50 mTorr, more preferably below 20 mTorr. For medium density plasma reactors, the reactor is preferably at a pressure above 20 mTorr, more preferably from 50 to 100 mTorr. Due to plasma confinement at the semiconductor substrate undergoing etching, the vacuum pressure at the substrate surface may be higher than the vacuum pressure setting for the reactor.

The substrate support supporting the semiconductor substrate undergoing etching preferably cools the substrate enough to prevent deleterious side reactions such as burning of any photoresist on the substrate and formation of undesirable reactant gas radicals. In high and medium density plasma reactors, it is sufficient to cool the bottom electrode to a temperature of −20 to +80° C. in order to obtain a substrate temperature of −20 to +200° C. The substrate support can include a bottom electrode for supplying an RF bias to the substrate during processing thereof and an ESC for clamping the substrate. For example, the substrate can comprise a silicon wafer which is electrostatically clamped and cooled by supplying helium (He) at a desired pressure between the wafer and top surface of the ESC. In order to maintain the wafer at a desired temperature of the He can be maintained at a pressure of 2 to 30 Torr in the space between the wafer and the chuck.

The foregoing has described the principles, preferred embodiments and modes of operation of the present invention. However, the invention should not be construed as being limited to the particular embodiments discussed. Thus, the above-described embodiments should be regarded as illustrative rather than restrictive, and it should be appreciated that variations may be made in those embodiments by workers skilled in the art without departing from the scope of the present invention as defined by the following claims.

What is claimed is:

1. A method of etching a dielectric layer with selectivity to an underlying stop layer, comprising:
supporting a semiconductor substrate in a plasma etch reactor, the substrate including a dielectric layer over a stop layer;
supplying an etchant gas ti the plasma etch chamber; and
etching openings in the dielectric layer by energizing the etchant gas into a plasma state, the etchant gas comprising a hydrogen-free fluorocarbon gas represented by CₓF_{y} gas wherein y/x≦1.5, an oxygen-containing gas and optional carrier gas.

2. The method of claim 1, wherein the openings comprise vias, contacts, and/or trenches of a dual damascene structure, a self-aligned contact (SAC) structure or self-aligned trench structure.

3. The method of claim 1, wherein the stop layer is silicon nitride and the etch rate selectivity of the dielectric to the silicon nitride ia at least 10.

4. The method of claim 1, wherein the dielectric layer comprises doped or undoped silicon oxide layer or low-k material and the stop layer comprises a silicon nitride layer.

5. The method of claim 1, wherein the plasma etch reactor comprises an ECR plasma reactor, an inductively coupled plasma reactor, a capacitively coupled plasma reactor, a helicon plasma reactor or a magnetron plasma reactor.

6. The method of claim 1, wherein the plasma etch reactor comprises a dual frequency capacitively coupled plasma reactor including an upper showerhead electrode and a bottom electrode, RF energy being supplied at two different frequencies to either the bottom electrode or at different first and second frequencies to the showerhead electrode and bottom electrode.

7. The method of claim 1, wherein the etchant gas is nitrogen-free, the CₓF_{y} gas is at least C₄F₆, the oxygen containing gas is at least O₂ and the carrier gas is Ar, the etchant gas being supplied to the plasma etch reactor through a showerhead electrode at flow rates of 2 to 50 SCCM C₄F₆, 2 to 50 sccm O₂ and 50 to 800 sccm Ar.

8. The method of claim 1, wherein the CₓF_{y} gas is at least C₄F₆, the oxygen containing gas is at least O₂ and the carrier gas is Ar, the etchant gas being supplied to the plasma etch reactor through a showerhead electrode at flow rates of 10 to 25 sccm C₄F₆, 5 to 20 sccm O₂ and 50 to 300 sccm Ar.

9. The method of claim 1, wherein a ratio of flow rates of the CₓF_{y} to oxygen containing reactant is 0.5:1 to 5:1.

10. The method of claim 1, wherein a ratio of flow rates of the CₓF_{y} to oxygen containing reactant is 1:1 to 2:1.

11. The method of claim 1, wherein pressure in the plasma etch reactor is 10 to 200 mTorr and/or temperature of the substrate support is −20° C. to +80° C.

12. The method of claim 1, wherein pressure in the plasma etch reactor is 50 to 100 mTorr and/or temperature of the substrate support is +20° C. to +60° C.

13. The method of claim 1, wherein the plasma etch reactor is a capacitively coupled plasma reactor having a powered showerhead electrode and/or a powered bottom electrode, the showerhead electrode being supplied 0 to 3000 watts of RF energy and the bottom electrode being supplied 0 to 3000 watts of RF energy.

14. The method of claim 1, wherein the etchant gas includes CO supplied to the plasma etch reactor at a rate of 50 to 500 sccm CO.

15. The method of claim 1, wherein the CₓF_{y} is either C₄F₆ or C₆F₆.

16. The method of claim 1, wherein the CₓF_{y} is C₄F₆ and the oxygen containing gas is O₂, the C₄F₆ and O₂ being supplied to the plasma etch reactor at flow rates having a ratio of C₄F₆:O₂ of 0. 5:1 to 5:1.

17. The method of claim 1, wherein the CₓF_{y} is C₄F₆ and the oxygen containing gas is O₂, the C₄F₆ and O₂ being supplied to the plasma etch reactor at flow rates having a ratio of C₄F₆:O₂ of 1:1 to 2:1.

18. The method of claim 1, wherein the CₓF_{y} is C₄F₆ and the oxygen containing gas is supplied to the plasma etch chamber in an amount sufficient to avoid etch stop during etching of the openings.

19. The method of claim 1, wherein the etched openings open onto flat and corner portions of the stop layer, the dielectric layer comprises BPSG and the stop layer comprises silicon nitride, the etch rate selectivity of the BPSG to the flat and corner portions of tyhe silicon nitride being at least 15.

20. The method of claim 1, wherein the dielectric layer comprises BPSG and the stop layer comprises silicon nitride, the CₓF_{y} gas being C₄F₆ and the oxygen containing gas being O₂, the C₄F₆ and O₂ being supplied to the plasma etch reactor at flow rates having a ratio of O₂:C₄F₆ of 0.5 to 1.2.
